(19) United States
(12) Patent Application Publication
(10) Pub. No.: US 2018/0090630 A1
(43) Pub. Date: Mar. 29, 2018

(54) PHOTOELECTRIC CONVERSION ELEMENT, MULTI-JUNCTION PHOTOELECTRIC CONVERSION ELEMENT, SOLAR CELL MODULE, AND SOLAR POWER SYSTEM

(71) Applicant: KABUSHIKI KAISHA TOSHIBA, Tokyo (JP)

(72) Inventors: Sara Yoshio, Taito Tokyo (JP); Naoyuki Nakagawa, Setagaya Tokyo (JP); Hiroki Hiraga, Saitama Saitama (JP); Soichiro Shibasaki, Nerima Tokyo (JP); Miyuki Shiokawa, Kawasaki Kanagawa (JP); Mutsuki Yamazaki, Yokohama Kanagawa (JP); Kazushige Yamamoto, Yokohama Kanagawa (JP)

(21) Appl. No.: 15/444,480

(22) Filed: Feb. 28, 2017

(30) Foreign Application Priority Data
Sep. 23, 2016 (JP) 2016-185998

(51) Int. Cl. H01L 31/032; H01L 31/046; H01L 31/0224; H01L 31/047

(52) U.S. Cl. CPC H01L 31/0322; H01L 31/047; H01L 31/022425; H01L 31/046

(57) ABSTRACT

A photoelectric conversion element of an embodiment includes a first electrode, a second electrode, a light-absorbing layer having a compound containing group I-III-VI elements between the first electrode and the second electrode, and an n-type layer between the light-absorbing layer and the second electrode. A group IV element is contained in the light-absorbing layer closer to the n-type layer. A maximum peak of the concentration of group IV element exists in a region down to a depth of 0.2 μm from a main surface of the light-absorbing layer facing to the n-type layer toward the first electrode.

### CROSS-REFERENCE TO RELATED APPLICATION

This application is based upon and claims the benefit of priority from Japanese Patent Application No. 2016-185998, filed on Sep. 23, 2016; the entire contents of which are incorporated herein by reference.

### FIELD

Embodiments described herein relate to a photoelectric conversion element, a multi-junction photoelectric conversion element, a solar cell module, and solar power system.

### BACKGROUND

A photoelectric conversion element using a compound, which uses a semiconductor thin film as light-absorbing layer, has been developed, and particularly a thin-film photoelectric conversion element using a group I-III-VI compound having a chalcopyrite configuration, such as Cu(In, Ga)Se₂ or CuGaSe₂, as light-absorbing layer (CIGS, CGS) demonstrates a high conversion efficiency. A solar cell module and a solar power system using the same are provided. A further enhancement in conversion efficiency is desired in a CIGS-based photoelectric conversion element.

### BRIEF DESCRIPTION OF THE DRAWINGS

FIG. 1 is a conceptual cross-section diagram of a photoelectric conversion element according to an embodiment;

FIG. 2 is a conceptual perspective diagram of part of the photoelectric conversion element according to the embodiment;

FIG. 3 illustrates a SIMS result according to the embodiment;

FIG. 4 illustrates an EDX result according to the embodiment;

FIG. 5 is a conceptual cross-section diagram of a multi-junction photoelectric conversion element according to an embodiment;

FIG. 6 is a conceptual diagram of a solar cell module according to an embodiment;

FIG. 7 is a conceptual diagram of a solar power system according to an embodiment; and

FIG. 8 illustrates J-V curves of a solar cell according to an example and a comparative example.

### DETAILED DESCRIPTION

A photoelectric conversion element of an embodiment includes a first electrode, a second electrode, a light-absorbing layer having a compound containing group I-III-VI elements between the first electrode and the second electrode, and an n-type layer between the light-absorbing layer and the second electrode. A group IV element is contained in the light-absorbing layer closer to the n-type layer. A maximum peak of the concentration of group IV element exists in a region down to a depth of 0.2 μm from a main surface of the light-absorbing layer facing to the n-type layer toward the first electrode.

An embodiment of the present disclosure will be described below with reference to the drawings.

### First Embodiment

(Photoelectric Conversion Element)

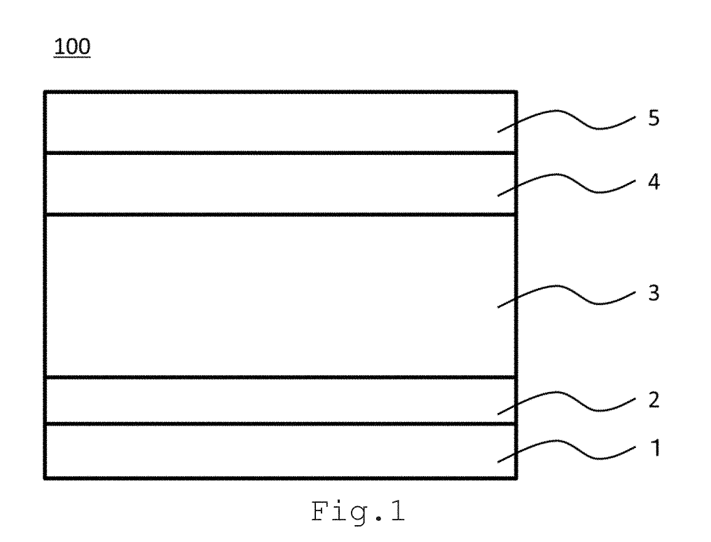

As illustrated in FIG. 1, a photoelectric conversion element 100 according to the present embodiment includes a substrate 1, a first electrode 2 on the substrate 1, a light-absorbing layer 3, an n-type layer 4, and a second electrode 5. The light-absorbing layer 3 and the n-type layer 4 are present between the first electrode 2 and the second electrode 5. Further, the light-absorbing layer 3 is present between the first electrode 2 and the n-type layer 4. The photoelectric conversion element according to the embodiment is a solar cell, for example.

(Substrate)

The substrate 1 according to the embodiment desirably employs soda-lime glass, and may employ any glass such as quartz, white glass, or chemically-reinforced glass, a metal plate such as stainless, Ti (Titanium), or Cr (Chromium), or resin such as polyimide or acryl.

(First Electrode)

The first electrode 2 according to the embodiment is an electrode of the photoelectric conversion element. The first electrode 2 is a first metal film or semiconductor film formed on the substrate 1, for example. The first electrode 2 is present between the substrate 1 and the light-absorbing layer 3. The first electrode 2 can employ a conductive metal film (first metal file) containing Mo or W, or a semiconductor film containing at least indium-tin oxide (ITO). The first metal film is preferably a Mo film or W film. A layer containing an oxide such as SnO₂, TiO₂, carrier-doped ZnO:Ga, or ZnO:Al may be laminated on the ITO closer to the light-absorbing layer 3. When the first electrode 2 employs a semiconductor film, ITO and SnO₂ may be laminated from the substrate 1 side toward the light-absorbing layer 3 side, or ITO, SnO₂, and TiO₂ may be laminated from the substrate 1 side toward the light-absorbing layer 3 side. A layer containing an oxide such as SiO₂ may be provided between the substrate 1 and ITO. The first electrode 2 can be sputtered thereby to be formed on the substrate 1. A film thickness of the first electrode 2 is between 100 nm and 1000 nm. When the photoelectric conversion element according to the embodiment is used as a multi-junction photoelectric conversion element, it is preferable that the photoelectric conversion element according to the embodiment is present closer to the top cell and the first electrode 2 is a transparent semiconductor film. The multi-junction photoelectric conversion element is a multi-junction solar cell, for example.

(Light-Absorbing Layer)

The light-absorbing layer 3 according to the embodiment is a p-type compound semiconductor layer. The light-absorbing layer 3 is present between the first electrode 2 and the n-type layer 4. The light-absorbing layer 3 contains a compound containing group I, group III, and group VI elements. The group I element preferably contains at least Cu. The group III element preferably contains at least Ga. The group VI element preferably contains at least Se. The light-absorbing layer may employ a compound semiconductor layer having a chalcopyrite configuration such as Cu(In, Ga)Se₂, CuInTe₂, CuGaSe, Cu(In, Al)Se, Cu(Al, Ga) (S, Se)₂, CuGa(S, Se)₂, or Ag(In, Ga)Se₂ containing a group I (Ib) element, a group III (IIIb) element and a VI (VIb) group element. It is preferable that the group Ib elements include Cu or Cu and Ag, the group IIIb elements are one or more elements selected from the group consisting of Ga, Al, and In, and the VIb group elements are one or more elements selected from the group consisting of Se, S, and Te. In particular, it is preferable that the group Ib elements include Cu, the group IIIb elements include Ga, Al, or both of Ga and Al, and the group VIb elements include Se, S, or both of Se and S. It is preferable that a band gap of the light-absorbing layer 3 can be easily adjusted at a suitable value as a top cell of the multi-junction photoelectric conversion element at a small amount of In in the group IIIb elements. A film thickness of the light-absorbing layer 3 is between 800 nm and 3000 nm, for example.

It is possible to easily adjust the band gap at a desired value in a combination of elements. A desired value of the band gap is between 1.0 eV and 1.7 eV, for example.

A group IV element is preferably contained in the light-absorbing layer 3 closer to the n-type layer 4 thereby to enhance a short-circuit current density (mA/cm²). The enhancement in short-circuit current density contributes to an enhancement in conversion efficiency of the photoelectric conversion element. The group IV elements contained in the light-absorbing layer 3 closer to the n-type layer 4 are preferably one or more elements selected from the group consisting of Ge, Si, and Sn. The group IV elements contained in the light-absorbing layer 3 closer to the n-type layer 4 are more preferably Ge, Si, or both of Ge and Si. The group IV element contained in the light-absorbing layer 3 closer to the n-type layer 4 is more preferably Ge. Ge, Si, and Sn are n-type dopants, and are assumed to shift the light-absorbing layer 3 closer to the n-type layer 4 to the n-type, which contributes to formation of an excellent pn junction. When the group IV elements are diffused inside the light-absorbing layer 3, the p-type inside the light-absorbing layer 3 shifts to the n-type, and thus it is preferable that the group IV elements are present in the light-absorbing layer 3 closer to the n-type layer 4 and are not or are rarely present inside the light-absorbing layer 3.

The light-absorbing layer 3 closer to the n-type layer 4 is a region in the light-absorbing layer 3 down to a depth of 0.2 μm from the main surface of the light-absorbing layer 3 facing to the n-type layer 4 toward the first electrode 2. The inside of the light-absorbing layer 3 is a region in the light-absorbing layer 3 between a depth of 0.5 μm from the main surface of the light-absorbing layer 3 facing to the n-type layer 4 toward the first electrode 2 and a depth of 0.7 μm toward the first electrode 2. The main surface of the light-absorbing layer 3 facing to the n-type layer 4 is a main surface of the light-absorbing layer 3 closer to the n-type layer 4.

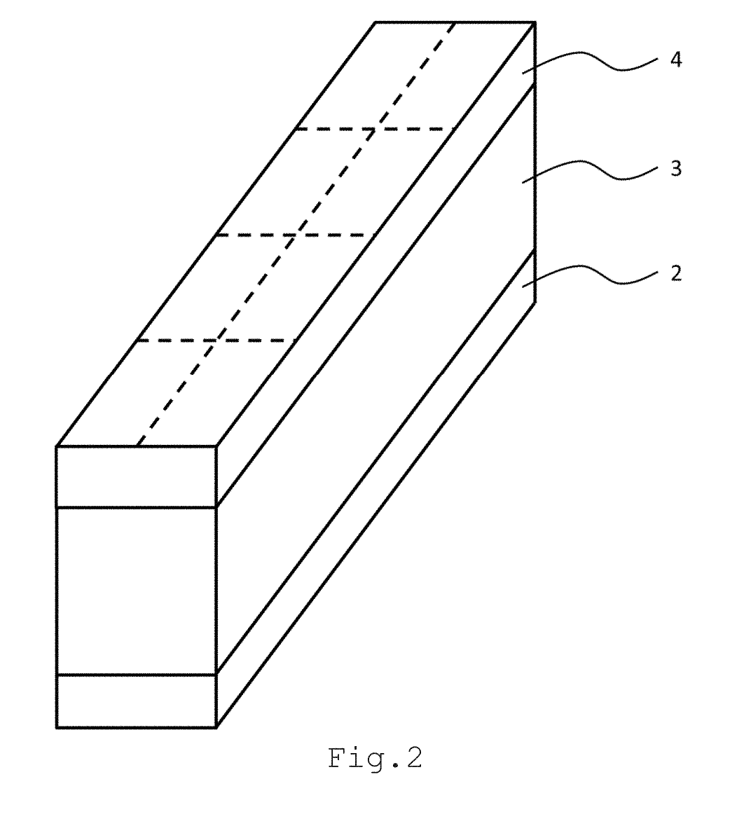

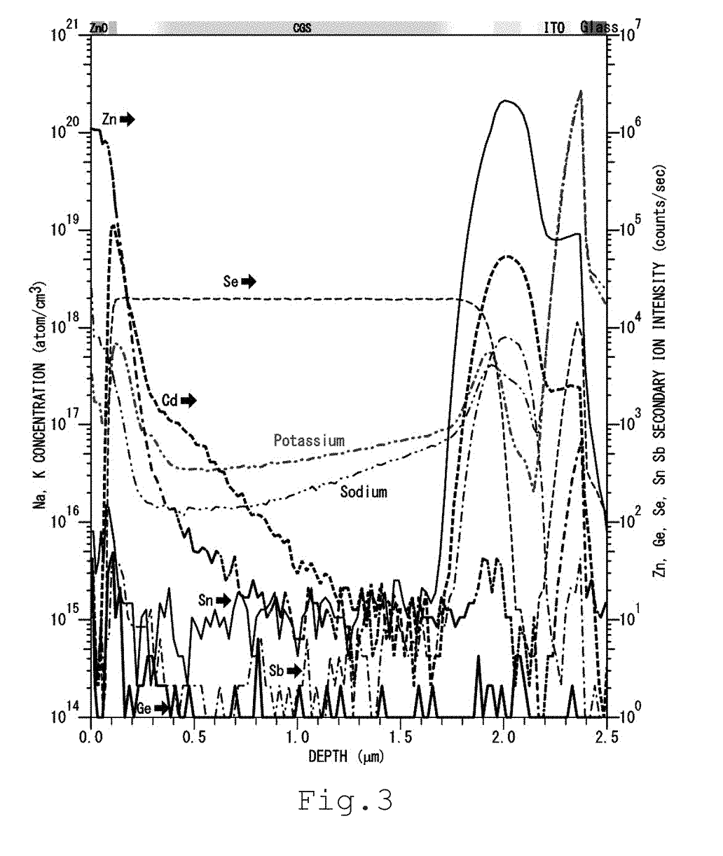

An analysis by a secondary ion mass spectrometry (SIMS) can confirm that a group IV element is contained in the light-absorbing layer 3 closer to the n-type layer 4. A cross section of the photoelectric conversion element is observed by a scanning electron microscope (SEM) and an element analysis is made by an energy dispersive X-ray spectrometry (EDX) thereby to specify the positions of the light-absorbing layer 3 and the n-type layer 4 in the photoelectric conversion element. An analysis in the depth direction from the n-type layer 4 toward the light-absorbing layer 3 is made by SIMS. A position to be analyzed is a region of 78 μm×78 μm at the center of eight regions obtained by dividing the n-type layer 4 into four regions in the long-side direction and into two regions in the short-side direction as illustrated in the conceptual perspective diagram of part of the photoelectric conversion element of FIG. 2. A SIMS measurement device employs PHI ADEPT1010, a primary ion species is Cs⁺, and a primary acceleration voltage is 5.0 kV. FIG. 3 illustrates a SIMS result confirming that a group IV element is contained in the light-absorbing layer 3 closer to the n-type layer 4. In FIG. 3, a bold line indicates Ge, a thin line indicates Sn, a bold broken line indicates Cd, a thin broken line indicates Se, a bold one-dotted broken line indicates Zn, a thin one-dotted broken line indicates Sb, a thin and dark two-dotted broken line indicates Na, and a bold and bright two-dotted broken line indicates K.

A group III element in the light-absorbing layer 3 closer to the n-type layer 4 is then found by a value found by the SIMS analysis. The light-absorbing layer 3 closer to the n-type layer 4 and the inside of the light-absorbing layer 3 are within the above range. An average concentration of the group III element found by the SIMS analysis in the light-absorbing layer 3 closer to the n-type layer 4 is assumed as group III element concentration S1 in the light-absorbing layer 3 closer to the n-type layer 4. The fact that a group IV element at a concentration of 0.1% or more of the group III element concentration S1 in the light-absorbing layer 3 closer to the n-type layer 4 is detected in the light-absorbing layer 3 closer to the n-type layer 4 indicates that a group IV element is contained in the light-absorbing layer 3 closer to the n-type layer 4.

A group I element is low in its diffusion property, and thus is easy to be at a low concentration in the light-absorbing layer 3 closer to the n-type layer 4. An average concentration of the group I element in the light-absorbing layer 3 closer to the n-type layer 4 is assumed as group I element concentration S2 in the light-absorbing layer 3 closer to the n-type layer 4. Similarly, an average concentration of the group I element inside the light-absorbing layer 3 is assumed as group I element concentration S3 inside the light-absorbing layer 3. The group I element concentration S2 in the light-absorbing layer 3 closer to the n-type layer 4 is easy to be lower than the group I element concentration S3 inside the light-absorbing layer 3. The group I element concentration S2 closer to the n-type layer 4 is lower so that the conductive type on the n-type layer 4 side easily shifts to the p-type than the inside conductive type. The n-type layer 4 side then enters p+ type. According to the embodiment, a group IV element is contained in the light-absorbing layer 3 closer to the n-type layer 4 so that the conversion efficiency of the photoelectric conversion element is enhance in the photoelectric conversion element having the relationship of the group I element concentration. The group I element concentration and the group IV element concentration in the light-absorbing layer 3 can be analyzed in the same method as the group III element concentration measurement method. The group I element concentration S2 in the light-absorbing layer 3 closer to the n-type layer 4 is preferably lower than the average concentration of the group I element in the region between a depth of 0.2 μm from the main surface of the light-absorbing layer 3 facing to the n-type layer 4 toward the first electrode 2 and a depth of 0.5 μm toward the first electrode 2.

A group I element average concentration in the light-absorbing layer 3 closer to the n-type layer 4 and a group I element average concentration inside the light-absorbing layer 3 are found by the group I element concentration S2 in the light-absorbing layer 3 closer to the n-type layer 4 and the group I element concentration S3 inside the light-absorbing layer 3, respectively, by the following measurement. At first, a cross section including the light-absorbing layer 3 is observed by a scanning transmission electron microscopy (STEM). A cross section (thin piece) orthogonal to the main surface of the substrate 1 of the photoelectric conversion element is prepared by a focused ion beam system (FIB). The cross section is adjusted in its position to include the center of the light-absorbing layer 3, thereby obtaining a thin-piece cross section. The resultant cross section is observed by the STEM. A scanning transmission electron microscopy (JEM-ARM200F) manufactured by JEOL Ltd. is used for the observation. The observation conditions are an acceleration voltage of 200 kV, magnifications of 48,000 times power and 400,000 times power, and a beam diameter of 0.1 nm. At first, an entire observation is made at 48,000 times power thereby to search a discontinuous crystal face. The discontinuous crystal face is observed at 400,000 times power thereby to estimate an interface position and a position of the light-absorbing layer 3.

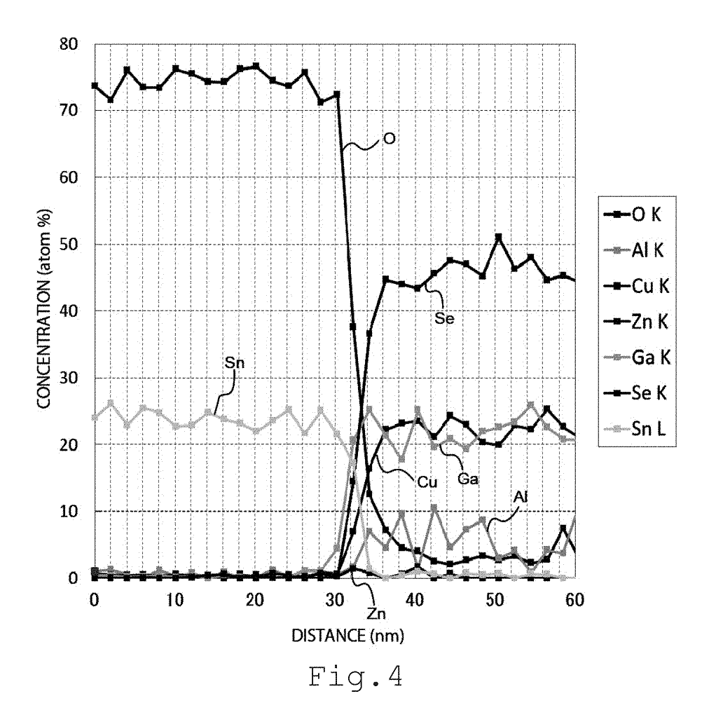

An element analysis is made by an energy dispersive X-ray spectrometry (EDX) for the light-absorbing layer 3. A position to be measured is at the center of the region illustrated in FIG. 2 described by the SIMS analysis. The analysis is made over the n-type layer 4 and the light-absorbing layer 3. The element analysis is made by use of the scanning transmission electron microscopy (JEM-ARM200F) manufactured by JEOL Ltd. and the element analyzer (JED-2300T) (STEM-EDX). The analysis conditions are an acceleration voltage of 200 kV, magnifications of 48,000 times power and 400,000 times power, a beam diameter of about 0.1 nm which are the same conditions for STEM, an X-ray detector as SI drift detector, an energy resolution of 140 EV, an X-ray pullout angle of 21.9°, and a fetch time of 1 sec/point. A boundary face between the main surface of the light-absorbing layer 3 facing to the n-type layer 4 and the main surface of the n-type layer 4 facing to the light-absorbing layer 3, or an interface between the light-absorbing layer 3 and the n-type layer 4 is assumed at a point where a group I element concentration (Cu element concentration+Ag element concentration) is higher than a sum of Zn element concentration, Cd element concentration and P element concentration (Zn element concentration+Cd element concentration+P element concentration) found in the n-type layer 4. When a layer estimated as the light-absorbing layer 3 by EDX analysis and STEM observation is not the light-absorbing layer 3, other layer is subjected to EDX analysis. A position of the light-absorbing layer 3 is specified by the resultant composition thereby to make the above analysis again. FIG. 4 illustrates the EDX results confirming that a group I element is at a low concentration in the light-absorbing layer 3 closer to the n-type layer 4. It is seen that a boundary between the light-absorbing layer 3 and the n-type layer 4 is present at a distance of about 33 nm on the basis of the STEM observation and the EDX result, and it is confirmed that a concentration of Cu element is lower near the boundary than Se element and Ga element.

The group I element concentration S2 in the light-absorbing layer 3 closer to the n-type layer 4 may be comparable with the group I element concentration S3 inside the light-absorbing layer 3 depending on a manufacture method. The fact that a difference between the group I element concentration S2 in the light-absorbing layer 3 closer to the n-type layer 4 and the group I element concentration S3 inside the light-absorbing layer 3 (([the group I element concentration S3 inside the light-absorbing layer 3]−[the group I element concentration S2 in the light-absorbing layer 3 closer to the n-type layer 4])/[the group I element concentration S3 inside the light-absorbing layer 3]) is less than 10% or less assumes that the group I element concentration S2 in the light-absorbing layer 3 closer to the n-type layer 4 is comparable with the group I element concentration S3 inside the light-absorbing layer 3. When the group I element concentration is comparable with those of the light-absorbing layer 3 closer to the n-type layer 4 and the inside of the light-absorbing layer 3, the n-type layer 4 side is not p+ type or is difficult to be p+ type. When a difference between the group I element concentration S2 in the light-absorbing layer 3 closer to the n-type layer 4 and the group I element concentration inside the light-absorbing layer 3 is 10% or more, the group I element concentration S2 in the light-absorbing layer 3 closer to the n-type layer 4 is assumed to be lower than the group I element concentration S3 inside the light-absorbing layer 3. Thus, when the group I element concentration S2 in the light-absorbing layer 3 closer to the n-type layer 4 is lower than the group I element concentration S3 inside the light-absorbing layer 3, an effect of enhanced conversion efficiency due to the group IV element is remarkable. It is preferable that a maximum peak of the concentration of group IV element exists in a region down to a depth of 0.2 μm from a main surface of the light-absorbing layer facing to the n-type layer toward the first electrode. The peak of the concentration of group IV can be observed by the above SIMS analysis.

It is not preferable that a group IV element present in the light-absorbing layer 3 closer to the n-type layer 4 is too plenty that the interface between the light-absorbing layer 3 and the n-type layer 4 is to become n+ type. An average concentration of the group IV element in the light-absorbing layer 3 closer to the n-type layer 4 is assumed as the group IV element concentration S4 in the light-absorbing layer 3 closer to the n-type layer 4. The group I element concentration S4 in the light-absorbing layer 3 closer to the n-type layer 4 is preferably 2% or less of the group III element concentration S1 in the light-absorbing layer 3 closer to the n-type layer 4. The group IV element concentration S4 in the light-absorbing layer 3 closer to the n-type layer 4 is preferably between 1% and 2% of the group III element concentration S1 in the light-absorbing layer 3 closer to the n-type layer 4. Because of the same reason, the group IV element concentration S4 in the light-absorbing layer 3 closer to the n-type layer 4 is preferably between 1% and 2% of the group III element concentration Si in the light-absorbing layer 3 closer to the n-type layer 4.

It is not preferable that a group IV element is contained inside the light-absorbing layer 3 because the inside of the light-absorbing layer 3 shifts to n-type. Thus, it is preferable that a group IV element is not present or is rarely present inside the light-absorbing layer 3. Assuming a concentration of a group IV element present in the region down to a depth of 0.2 μm from the main surface of the light-absorbing layer 3 facing to the n-type layer 4 toward the first electrode 2 as X and a concentration of a group IV element present in a region between a depth of 0.5 μm from the main surface of the light-absorbing layer 3 facing to the n-type layer 4 toward the first electrode 2 and a depth of 0.7 μm toward the first electrode 2 as Y, X and Y preferably satisfy X/Y>100. Assuming a group IV element concentration S5 inside the light-absorbing layer 3, the group IV element concentration S5 inside the light-absorbing layer 3 is preferably between 0.0% and 5.0% of the group IV element concentration S4 in the light-absorbing layer 3 closer to the n-type layer 4, and more preferably between 0.0% and 1.0% thereof.

A group I element is missing in the light-absorbing layer 3 closer to the n-type layer 4, and thus a phase partially made of a group III element and a group VI element may be contained in the light-absorbing layer 3 closer to the n-type layer 4. For example, assuming a group III element of Ga and a group VI element of Se, a GaSe phase is present in the light-absorbing layer 3 closer to the n-type layer 4. It is preferable that at least some group IV elements are substituted with a group III element of Ga and a GaMSe phase is present in the light-absorbing layer 3 closer to the n-type layer 4. M is a group IV element and any one or more elements selected from the group consisting of Ge, Si and Sn. The substitution is assumed to be caused in a heating processing when a group IV element is diffused. The GaMSe phase can be confirmed depending on the presence of a peak of combination between a group VI element and a group IV element by the X-ray photoelectron spectroscopy (XPS). For example, assuming a group IV element of Ge and a group VI element of Se, a peak indicating a Ge—Se combination is observed at about 1218 eV.

A group VII element may be present in the light-absorbing layer 3 closer to the n-type layer 4. The group VII element is most preferably Cl, Br, or both of Cl and Br.

A group V element is preferably present closer to the substrate in the light-absorbing layer 3. The group V elements may be one or more elements selected from the group consisting of N, P, As, Sb, and Bi. Sb is preferable for the group V element. The group V element is a p-type dopant, and thus it is not preferable that a large amount of group V element is present in the light-absorbing layer 3 closer to the n-type layer 4. An average concentration of the group V element in the light-absorbing layer 3 closer to the n-type layer 4 is assumed as group V element concentration S6 in the light-absorbing layer 3 closer to the n-type layer 4. The group V element concentration S6 in the light-absorbing layer 3 closer to the n-type layer 4 is preferably lower than the group IV element concentration S4 in the light-absorbing layer 3 closer to the n-type layer 4. [The group V element concentration S6 in the light-absorbing layer 3 closer to the n-type layer 4]/[the group IV element concentration S4 in the light-absorbing layer 3 closer to the n-type layer 4] is preferably 0.1 or less. The group V element concentration S6 in the light-absorbing layer 3 closer to the n-type layer 4 is measured in a similar method as for the group IV element and the like.

(n-Type Layer)

The n-type layer 4 according to the embodiment is an n-type semiconductor layer. The n-type layer 4 is present between the light-absorbing layer 3 and the second electrode 5. The n-type layer 4 physically-directly contacts with the main surface of the light-absorbing layer 3 opposite to the first electrode 2. The n-type layer 4 is a heterojunction layer to the light-absorbing layer 3. The n-type layer 4 is preferably an n-type semiconductor controlled in Fermi level thereby to obtain a photoelectric conversion element with a high open voltage. The n-type layer 4 may employ Zn_{1-y}M_{y}O₁₋ₓSₓ, Zn_{1-y-z}Mg_{z}M_{y}O, ZnO₁₋ₓSₓ, Zn_{1-z}Mg_{z}O (M is at least one element selected from the group of B, Al, In and Ga), CdS, or carrier concentration-controlled n-type GaP. A thickness of the n-type layer 4 is preferably between 2 nm and 800 nm. The n-type layer 4 is manufactured by sputtering or chemical bath deposition (CBD), for example. When the n-type layer 4 is manufactured by CBD, it can be formed on the light-absorbing layer 3 by a chemical reaction between metallic salt (such as CdSO₄), sulfide (thiourea), and complexing agent (ammonia) in a solution, for example. When the light-absorbing layer 3 employs a chalcopyrite compound not containing In in the group IIIb elements, such as CuGaSe₂ layer, AgGaSe₂ layer, CuGaAlSe₂ layer, or CuGa(Se, S)₂ layer, CdS is preferable for the n-type layer 4.

A group IV element in the n-type layer 4 can be confirmed only at the interface with the light-absorbing layer 3, and is rarely present in the n-type layer 4.

(Oxide Layer)

An oxide layer according to the embodiment is a thin film which is preferably provided between the n-type layer 4 and the second electrode 5. The oxide layer is a thin film containing any one or more compounds selected from the group consisting of Zn₁₋ₓMgₓO, ZnO_{1-y}S_{y}, and Zn₁₋ₓMgₓO_{1-y}S_{y} (0≦x, y<1). The oxide layer may not cover all the main surface of the n-type layer 4 facing to the second electrode 5. For example, it may cover 50% of the surface of the n-type layer 4 closer to the second electrode 5. Any other candidates such as wurtzite AlN, GaN, and BeO may be employed. A volume resistivity of 1 Ωcm or more of the oxide layer is advantageous in that a leak current due to a low resistance component, which can be present in the light-absorbing layer 3, can be restricted. According to the embodiment, the oxide layer may be omitted. The oxide layer is an oxide particle layer and preferably has many gaps therein. An intermediate layer is not limited to the above compounds or physical properties, and may be any layer contributing to an enhancement in conversion efficiency of the photoelectric conversion element. A plurality of intermediate layers with different physical properties may be employed.

(Second Electrode)

The second electrode 5 according to the embodiment is an electrode film which transmits a light such as sunlight and is conductive. The second electrode 5 physically-directly contacts with the intermediate layer or the main surface of the n-type layer 4. The light-absorbing layer 3 and the n-type layer 4, which are joined to each other, are present between the second electrode 5 and the first electrode 2. The second electrode 5 is manufactured by sputtering in the Ar atmosphere, for example. The second electrode 5 may employ ZnO:Al using a ZnO target containing 2 wt % of alumina (Al₂O₃) or ZnO:B using B from diborane or triethyl boron as dopant, for example.

(Third Electrode)

A third electrode according to the embodiment is an electrode of the photoelectric conversion element 100, and is a metal film formed on the second electrode opposite to the light-absorbing layer 3. The third electrode may employ a conductive metal film such as Ni or Al. A film thickness of the third electrode is between 200 nm and 2000 nm, for example. The third electrode may be omitted when the second electrode 5 has a low resistance value and a negligibly-small amount of series resistance component.

(Anti-Reflective Film)

An anti-reflective film according to the embodiment is directed for easily introducing a light into the light-absorbing layer 3, and is formed on the second electrode 5 or the third electrode opposite to the light-absorbing layer 3. The anti-reflective film desirably employs MgF₂ or SiO₂, for example. The anti-reflective film may be omitted according to the embodiment.

(Manufacture Method)

A method for manufacturing the photoelectric conversion element according to the embodiment will be described below.

According to the present embodiment, at first, the first electrode 2 is formed on the substrate 1 by sputtering, for example. The light-absorbing layer 3 is formed on the first electrode 2 formed on the substrate 1 by sputtering, deposition (three-stage approach), or gas (Se method). The sputtering method is preferably performed at a substrate temperature of 500 to 640° C. in the highly-vacuum atmosphere, and is more preferably performed at as high a temperature as the substrate 1 is not distorted. When the temperature of the substrate 1 is too low, the light-absorbing layer 3 is deteriorated in its crystalline property, which can cause a reduction in conversion efficiency. Annealing may be performed after the film is formed. At a Cu concentration of the light-absorbing layer 3 closer to the main surface (the n-type layer 4) opposite to the first electrode 2, a deposition rate is adjusted or a three-stage approach is employed for the method for manufacturing the light-absorbing layer 3.

After the light-absorbing layer 3 is formed, the surface of the light-absorbing layer 3 is processed by a group IV element. It is preferable to employ a soaking method for soaking the surface of the light-absorbing layer 3 (the surface where the n-type layer 4 is formed later) in a compound containing a liquid group IV element. The compound containing a liquid group IV element preferably employs a compound MX containing a group IV element of M and a group VII element of X. This is because the compound is high in its reactivity and easily diffuses into the surface layer of the p-type light-absorbing layer 3 (closer to the n-type layer) in the heating processing. Thereafter, the heating processing is performed so that the group IV element diffuses into the light-absorbing layer 3. For example, it is preferably performed in the inactive atmosphere such as nitrogen and at a temperature of 50° C. to 300° C. The group IV element is preferably Si or Ge. This is because particularly Si and Ge in the group IV elements react in the soaking process at a normal temperature.

The surface of the light-absorbing layer 3 is soaked in the compound MX containing a group IV element of M and a group VII element of X and then heated, and thus a group IV element (n-type dopant) is added thereto. The soaking time and the heating temperature or time are different depending on a dopant to be used. Additionally, any method for applying the MX solution to the surface by spin-coating and then heating the same may be employed.

The n-type layer 4 is formed on the p-type semiconductor layer 3 subjected to the surface processing. The method for forming the n-type layer 4 may be soaking, spraying, deposition, or application. When an n-type semiconductor layer is formed by the soaking method, a solution temperature is preferably between 40 and 100° C., and more preferably at about 80° C. The film formation speed is low at so low a solution temperature. It is difficult for an n-type semiconductor layer to form since an ammonia solution boils at so high a solution temperature.

After the n-type layer 4 is formed, an intermediate layer is formed on the n-type layer 4 by a spin-coating method, for example. Then, the second electrode 5 is sputtered to be formed on the intermediate layer and the third electrode is sputtered to be formed on the second electrode 5. An anti-reflective film is preferably sputtered to be formed on the second electrode 5 or the third electrode.

In order to contain a group V element in the light-absorbing layer 3, a method for processing the first electrode 2 in a solution containing a group V element and then forming the light-absorbing layer 3 can be employed. Then, it is preferable that many group V elements are distributed closer to the first electrode 2 and a group V element concentration is low in the light-absorbing layer 3 closer to the n-type layer 4.

### Second Embodiment

(Multi-Junction Photoelectric Conversion Element)

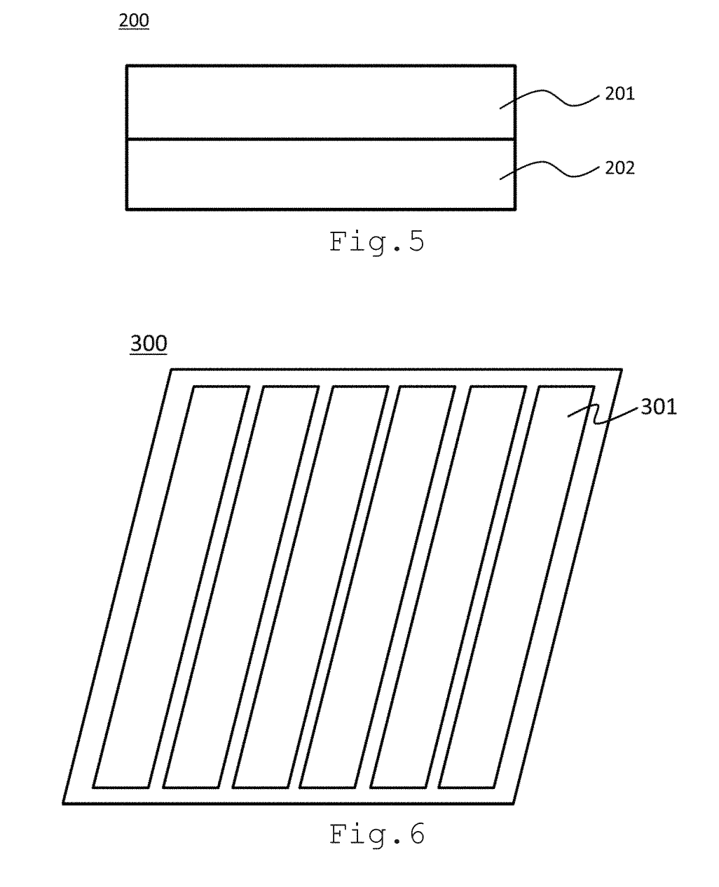

A second embodiment is a multi-junction photoelectric conversion element using the photoelectric conversion element according to the first embodiment. FIG. 5 is a schematic cross-section diagram of the multi-junction photoelectric conversion element according to the second embodiment. The multi-junction photoelectric conversion element of FIG. 5 includes a top-cell photoelectric conversion element 201 and a bottom-cell photoelectric conversion element 202. When a photoelectric conversion element having an Si light-absorbing layer is used for the bottom cell and the photoelectric conversion element according to the first embodiment is used for the top cell, a group I element of Cu, a group III element of Ga, and a group VI element of Se are preferable in terms of absorption wavelength and conversion efficiency. The light-absorbing layer in the photoelectric conversion element according to the first embodiment is a wide gap, and thus is preferably used for the top cell. The multi-junction photoelectric conversion element is a multi-junction solar cell, for example.

### Third Embodiment

(Solar Cell Module)

The photoelectric conversion element according to the first or second embodiment can be used as a power generation device in a solar cell module according to a third embodiment. Power generated by the photoelectric conversion element according to the embodiment is consumed in the load electrically connected to the photoelectric conversion element, or saved in a secondary cell electrically connected to the photoelectric conversion element.

The solar cell module according to the third embodiment may be configured such that a member in which a plurality of solar cells are connected in series, in parallel, or in series and parallel, or a single cell is fixed to a support member made of glass and the like. The solar cell module may be provided with a light focusing body and may be configured to convert a light received in a larger area than the area of the solar cells into power. The solar cells may include solar cells connected in series, in parallel, or in series and parallel.

FIG. 6 is a conceptual configuration diagram of a solar cell module 300 in which six solar cells 301 are arranged side by side. The solar cell module 300 of FIG. 6 is preferably configured such that a plurality of solar cells 301 are connected in series, in parallel, or in series and parallel as described above, though connection wirings are not illustrated. The solar cell 301 preferably employs the photoelectric conversion element according to the first embodiment or the multi-junction solar cell 200 according to the second embodiment. The solar cell module 300 according to the embodiment may employ a module configuration in which modules using the photoelectric conversion element according to the first embodiment or the multi-junction solar cell 200 according to the second embodiment and modules using another solar cell are laminated. Any other configuration for enhancing conversion efficiency is preferably employed. The solar cells 301 have a wide band-gap photoelectric conversion layer, and thus is preferably provided on the light receiving face side in the solar cell module 300 according to the embodiment.

### Fourth Embodiment

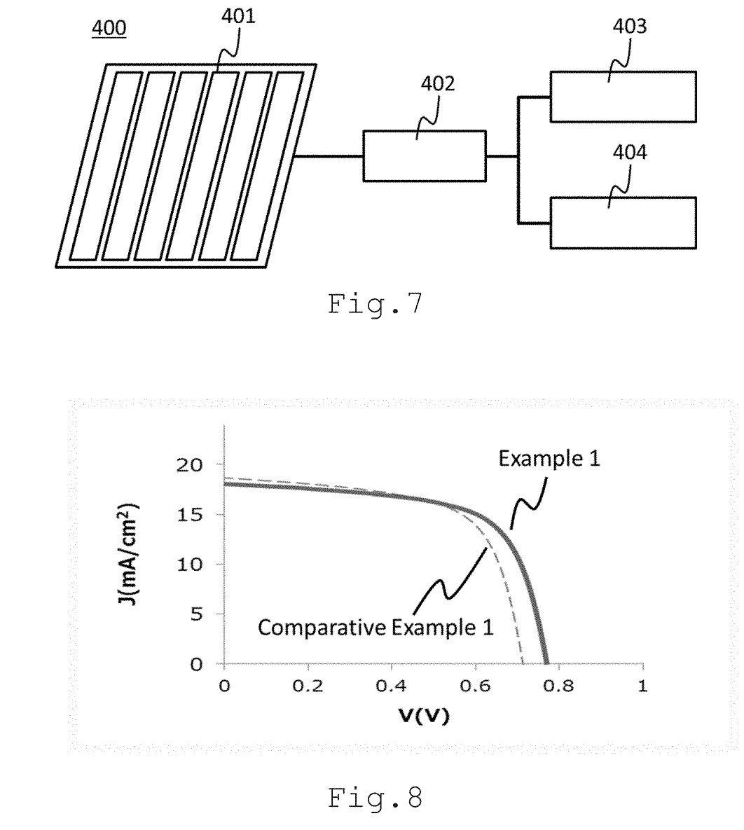

The solar cell module 300 according to the embodiment can be used as a motor for generating power in a solar power system according to a fourth embodiment. The solar power system according to the embodiment is directed for generating power by use of the solar cell module, and specifically includes the solar cell module for generating power, a unit configured to convert generated electricity into power, and an accumulation unit configured to accumulate generated electricity or a load configured to consume generated electricity. FIG. 7 is a conceptual configuration diagram of a solar power system 400 according to the embodiment. The solar power system of FIG. 7 includes a solar cell module 401 (300), a converter 402, a secondary cell 403, and a load 404. Either the secondary cell 403 or the load 404 may be omitted. The load 404 may be configured to use electric energy accumulated in the secondary cell 403. The converter 402 is a device including circuit or device for performing power conversion such as transformation or DC/AC conversion, such as DC-DC converter, DC-AC converter, or AC-AC converter. The converter 402 may employ a suitable configuration depending on power generation voltage or the configuration of the secondary cell 403 or the load 404.

The solar cells 301 receiving a light, which are included in the solar cell module 300, generate power, and its electric energy is converted by the converter 402 and accumulated in the secondary cell 403 or consumed in the load 404. The solar cell module 401 is preferably provided with a solar tracking/driving device for always facing the solar cell module 401 toward the sun, is provided with a light focusing body for focusing a sunlight, or is added with a device for enhancing power generation efficiency.

The solar power system 400 is preferably used in immovables such as dwellings, commercial facilities, and factories, or movables such as vehicles, airplanes, and electronic devices. The photoelectric conversion element excellent in conversion efficiency according to the embodiment is used for the solar cell module 401, and thus an increase in power generation is expected.

The embodiments will be specifically described below by way of examples, and the embodiments are not limited to the following examples.

### Example 1

A photoelectric conversion element according to Example 1 is manufactured in the following method. A film-like first electrode with a thickness of 500 nm, which is made of Mo alone, is sputtered to be formed on soda-lime glass with 25 mm length×25 mm width×1.8 mm thickness in the Ar stream. Cu, Ga, and Se are deposited (in three-stage approach) on the Mo electrode on the blue glass thereby to form a light-absorbing layer with a thickness of about 2 μm. At this time, a deposition rate is adjusted such that a Cu concentration on the surface is lower.

An n-type dopant is doped into the light-absorbing layer closer to the n-type layer 4 by the soaking method. The doping is performed in two steps of soaking and diffusion. At first, a member where the light-absorbing layer is formed is soaked in a doping solution containing GeCl₄ for 10 minutes. The step is performed in a glove box in the N₂ atmosphere at a dew point of −75° C. or more since moisture and oxygen are not good for the step. The doping solution is a GeCl₄ solution. At least the light-absorbing layer closer to the n-type layer 4 (the main surface of the light-absorbing layer opposite to the main surface of the first electrode), which is to be soaked, is soaked in the doping solution.

Thereafter, the soaked member is taken out and heated in the N₂ atmosphere at 150° C. for 10 minutes thereby to diffuse the dopant. Thereafter, CdS with a thickness of 20 nm is formed as an n-type layer by the CBD method. After the n-type layer is formed, a ZnMgO particle layer is formed at a thickness of 100 nm. About 200 nm of ZnO:Al is then sputtered on the ZnMgO layer thereby to form a second electrode An Al third electrode and an anti-reflective film are formed as pullout electrodes on the second electrode thereby to manufacture a photoelectric conversion element according to Example 1.

### Example 2

According to Example 2, a drug to be doped is changed to SiCl₄ in manufacturing the photoelectric conversion element according to Example 1. Other steps are performed as in Example 1 thereby to manufacture a photoelectric conversion element according to Example 2.

### Example 3

According to Example 3, a drug to be doped is changed to SnCl₄ in manufacturing the photoelectric conversion element according to Example 1. Other steps are performed as in Example 1 thereby to manufacture a photoelectric conversion element according to Example 3.

### Example 4

According to Example 4, a drug to be doped is changed to GeCl₄ in manufacturing the photoelectric conversion element according to Example 1. Other steps are performed as in Example 1 thereby to manufacture a photoelectric conversion element according to Example 4.

### Example 5

According to Example 5, a method for forming an ITO film with a thickness of 20 nm as first electrode by sputtering is employed in manufacturing the photoelectric conversion element according to Example 1. Other steps are performed as in Example 1 thereby to manufacture a photoelectric conversion element according to Example 5.

### Example 6

According to Example 6, a step of doping a p-type dopant on the surface of the ITO electrode is added in manufacturing the photoelectric conversion element according to Example 1. The p-type dopant is doped by soaking a member where the ITO electrode is formed on the substrate in an ethanol solution with 1 mol/L of SbCl₃ for 10 minutes and then heating it in the N₂ atmosphere at 100° C. for 10 minutes. Other steps are performed as in Example 1 thereby to manufacture a photoelectric conversion element according to Example 6.

### Example 7

According to Example 7, a drug to be doped is changed to GeBr₄ in manufacturing the photoelectric conversion element according to Example 1, and a hot plate is used for melting GeBr₄ to be kept at 50° C. during soaking. Further, a subsequent heating processing is performed at 200° C. in order to completely remove GeBr₄. Other steps are performed as in Example 1 thereby to manufacture a photoelectric conversion element according to Example 7.

### Comparative Example 1

According to Comparative example 1, a method omitting the doping step using an n-type dopant therefrom is employed in manufacturing the photoelectric conversion element according to Example 1. Other steps are similarly performed thereby to manufacture a photoelectric conversion element according to Comparative example 1.

### Comparative Example 2

According to Comparative example 2, a method for adjusting a deposition rate during the formation of a light-absorbing layer to achieve a uniform layer composition is employed in manufacturing the photoelectric conversion element according to Example 1. Other steps are similarly performed thereby to manufacture a photoelectric conversion element according to Comparative example 2.

### Comparative Example 3

According to Comparative example 3, a step of doping a p-type dopant into the surface of the ITO electrode is added in manufacturing the photoelectric conversion element according to Example 1. The p-type dopant is doped by soaking a member where the ITO electrode is formed on the substrate in an ethanol solution with 4 mol/L of SbCl₃ for 10 minutes and then heating it in the N₂ atmosphere at 100° C. for 10 minutes. Other steps are performed as in Example 1 thereby to manufacture a photoelectric conversion element according to Comparative example 3.

### Comparative Example 4

According to Comparative example 4, a drug to be doped is changed to TiCl₄ in manufacturing the photoelectric conversion element according to Example 1. Other steps are performed as in Example 1 thereby to manufacture a photoelectric conversion element according to Comparative example 4.

### Comparative Example 5

According to Comparative example 5, the heating/diffusion processing in the N₂ atmosphere is performed at 250° C. for 20 minutes after n-type doping in manufacturing the photoelectric conversion element according to Example 1. Other steps are performed as in Example 1 thereby to manufacture a photoelectric conversion element according to Comparative example 5.

### Comparative Example 6

According to Comparative example 6, a method for forming an ITO film with a thickness of 20 nm as first electrode by sputtering is employed in manufacturing the photoelectric conversion element according to Comparative example 1. Other steps are performed as in Comparative example 1 thereby to manufacture a photoelectric conversion element according to Comparative example 6.

(Evaluations of Photoelectric Conversion Elements)

STEM-EDX analysis is made in order to examine the presence of dopant and to make SIMS measurement and confirm a lack of Cu in the light-absorbing layer. Efficiency measurement is made by use of a solar simulator thereby to create a J-V curve.

The performance of each photoelectric conversion element according to Examples and Comparative examples is indicated in the following Table. The rates of Voc and conversion efficiency are indicated with reference to Comparative example 1.

TABLE 1

| | | | | Group V | | |
|---|---|---|---|---|---|---|
| | | | Composition of | element < | | |
| | Group | Group | surface of | group | | |
| | IV | VII | light-absorbing | VI | | Conversion |
| | element | element | layer | element | Voc V | efficiency % |
| Example 1 | Ge | Cl | Thin Cu | TRUE | 1.07 | 1.05 |
| Example 2 | Si | Cl | Thin Cu | TRUE | 1.05 | 1.04 |
| Comparative | — | — | Thin Cu | FALSE | 1.00 | 1.00 |
| example 1 | | | | | | |
| Comparative | Ge | Cl | Similar to under | FALSE | 1.00 | 1.00 |
| example 2 | | | middle | | | |
| Comparative | Ge | Cl | Thin Cu | FALSE | 0.80 | 0.75 |
| example 3 | | | | | | |

The performances of Examples 1 and 2 are comparable with or higher than the performances of the photoelectric conversion elements according to Comparative examples (the same lot of 8.0%). It is confirmed that Ge is present between the p-type light-absorbing layer and the n-type layer on the basis of the SIMS result. Further, more Ge is detected than Sb. It is further confirmed that C1 diffuses into the surface of the p-type light-absorbing layer. It is apparent that the effects of the embodiments are obtained based on the results. Ge demonstrates the most effective Voc enhancement among the group IV elements, and Si is the second most effective, and Sn demonstrates a slight increase thereof. Jsc seldom changes. As the soaking time is longer, the group VII elements on the CGS surface increase and an increase in Voc is also higher. The group IV elements are found also in Examples 3 to 7, and are excellent in conversion efficiency. Ti is used as dopant according to Comparative example 4, and thus the effect of enhanced conversion efficiency is lower than that in Examples. According to Comparative example 5, a large amount of group IV elements diffuse in the n-type layer, and thus the conversion efficiency is lowered. Doping is not performed according to Comparative example 6 as in Example 1, and thus the conversion efficiency is lower than that in Examples.

An excellent conversion efficiency can be obtained also in a multi-junction photoelectric conversion element using the photoelectric conversion element according to Example 5 as top cell and the photoelectric conversion element made of polycrystalline Si as bottom cell.

Here, some elements are expressed only by element symbols thereof.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photoelectric conversion element comprising:
a first electrode;
a second electrode;
a light-absorbing layer having a compound containing group I-III-VI elements between the first electrode and the second electrode; and
an n-type layer between the light-absorbing layer and the second electrode,
wherein a group IV element is contained in the light-absorbing layer closer to the n-type layer, and
a maximum peak of the concentration of group IV element exists in a region down to a depth of 0.2 μm from a main surface of the light-absorbing layer facing to the n-type layer toward the first electrode.

2. The element according to claim 1,
wherein the group IV element is present in the region down to a depth of 0.2 μm from a main surface of the light-absorbing layer facing to the n-type layer toward the first electrode.

3. The element according to claim 1,
wherein the group I elements include at least Cu,
the group III elements include at least Ga,
the group VI elements include at least Se, and
a compound in the light-absorbing layer is a chalcopyrite compound.

4. The element according to claim 1,
wherein the group IV elements include one or more elements selected from the group consisting of Ge, Si, and Sn.

5. The element according to claim 1,
wherein the light-absorbing layer closer to the n-type layer further contains a group VII element.

6. The element according to claim 1,
wherein when a concentration of the group IV element present in the region down to a depth of 0.2 μm from the main surface of the light-absorbing layer facing to the n-type layer toward the first electrode is assumed as X, and
a concentration of the group IV element present in a region between a depth of 0.5 μm from the main surface of the light-absorbing layer facing to the n-type layer toward the first electrode and a depth of 0.7 μm toward the first electrode is assumed as Y,
X and Y satisfy X/Y>100.

7. The element according to claim 1,
wherein a group I element concentration in the region down to a depth of 0.2 μm from the main surface of the light-absorbing layer facing to the n-type layer toward the first electrode is lower than a group I element concentration in a region between a depth of 0.5 μm from the main surface of the light-absorbing layer facing to the n-type layer toward the first electrode and a depth of 0.7 μm toward the first electrode.

8. The element according to claim 1,
wherein a group IV element concentration in the region down to a depth of 0.2 μm from the main surface of the light-absorbing layer facing to the n-type layer toward the first electrode is between 1% and 2% of a group III element concentration in the region down to a depth of 0.2 μm from the main surface of the light-absorbing layer facing to the n-type layer toward the first electrode.

9. A multi-junction photoelectric conversion element using the photoelectric conversion element according to claim 1.

10. A solar cell module using the photoelectric conversion element according to claim 1.

11. A solar cell module using the multi-junction photoelectric conversion element according to claim 9.

12. A solar power system for performing solar power generation by use of the solar cell module according to claim 10.

13. A solar power system for performing solar power generation by use of the solar cell module according to claim 11.
